(19) United States
(12) Patent Application Publication
(10) Pub. No.: US 2020/0272179 A1
(43) Pub. Date: Aug. 27, 2020

(54) OSCILLATOR, ELECTRONIC APPARATUS AND VEHICLE

(71) Applicant: SEIKO EPSON CORPORATION, Tokyo (JP)

(72) Inventor: Norihito MATSUKAWA, Shimosuwa-machi (JP)

(73) Assignee: SEIKO EPSON CORPORATION, Tokyo (JP)

(21) Appl. No.: 16/799,969

(22) Filed: Feb. 25, 2020

(30) Foreign Application Priority Data
Feb. 26, 2019 (JP) 2019-032735

(51) Int. Cl. G05D 23/19; H03B 5/04; H03B 5/36

(52) U.S. Cl. CPC G05D 23/1919; H03B 5/364; H03B 5/04

(57) ABSTRACT

Provided is an oscillator including: a resonant element; an oscillation circuit oscillating the resonant element; a first temperature sensor; a second temperature sensor that is provided at a location farther from the resonant element, than the first temperature sensor is; a temperature adjustment element adjusting a temperature of the resonant element; and a temperature control circuit generating a temperature control signal for controlling the temperature adjustment element on the basis of a temperature set value of the resonant element, a first temperature detection value detected by the first temperature sensor, and a temperature control correction value that is non-linear with respect to a second temperature.

The present application is based on, and claims priority from JP Application Serial Number 2019-032735, filed Feb. 26, 2019, the disclosure of which is hereby incorporated by reference herein in its entirety.

### BACKGROUND

### 1. Technical Field

The present disclosure relates to an oscillator, an electronic apparatus, and a vehicle.

### 2. Related Art

JP-A-2017-208637 describes a temperature oven controlled quartz crystal oscillator in which even when the actually measured temperature is changed on the basis of the outside air temperature, the temperature of the quartz crystal resonator can be made to have a zero inclination characteristic by adding a feedback amount, which is obtained by multiplying the temperature difference between the set temperature and the actually measured temperature by a predetermined feedback coefficient, to a target temperature of the quartz crystal resonator to obtain a new set temperature.

However, although the temperature oven controlled quartz crystal oscillator described in JP-A-2017-208637 performs a temperature control to make the temperature of the quartz crystal resonator has the zero inclination characteristic on the assumption that the actually measured temperature has a linear relationship with respect to the outside air temperature, due to complex factors such as wiring resistance inside the apparatus, the actually measured temperature may fluctuate more complexly with respect to the outside air temperature and the temperature control described in JP-A-2017-208637 is not always sufficient.

### SUMMARY

An oscillator according to an aspect of the present disclosure includes: a resonant element; an oscillation circuit oscillating the resonant element; a first temperature sensor; a second temperature sensor that is provided at a location farther from the resonant element than the first temperature sensor is; a temperature adjustment element adjusting a temperature of the resonant element; and a temperature control circuit generating a temperature control signal for controlling the temperature adjustment element on the basis of a temperature set value of the resonant element, a first temperature detection value detected by the first temperature sensor, and a temperature control correction value based on a second temperature detection value detected by the second temperature sensor, in which temperature control correction value approximates a characteristic opposite to a temperature change of the resonant element with respect to an outside air temperature change when the temperature control correction value is zero by a second-order or higher polynomial having the second temperature detection value as a variable.

An oscillator according to another aspect of the present disclosure includes: a resonant element; an oscillation circuit oscillating the resonant element; a first temperature sensor; a second temperature sensor that is provided at a location farther from the resonant element than the first temperature sensor is; a temperature adjustment element adjusting a temperature of the resonant element; and a temperature control circuit generating a temperature control signal for controlling the temperature adjustment element on the basis of a temperature set value of the resonant element, a first temperature detection value detected by the first temperature sensor, and a temperature control correction value that is non-linear with respect to a second temperature detection value detected by the second temperature sensor.

In the oscillator, the temperature control circuit may generate the temperature control signal by comparing a value obtained by adding the temperature set value to the temperature control correction value with the first temperature detection value.

In the oscillator, the temperature control circuit may generate the temperature control signal by comparing a value obtained by adding the first temperature detection value to the temperature control correction value with the temperature set value.

In the oscillator, the temperature control correction value may be non-linear with respect to the second temperature detection value in a first range of the second temperature detection value, and the temperature control correction value may be a fixed value regardless of the second temperature detection value in at least one of a lower limit or less of a first range and an upper limit or more of the first range.

The oscillator may include a temperature compensation circuit that compensates a frequency of the oscillation circuit on the basis of the second temperature detection value.

The oscillator may include a first circuit device and a second circuit device, in which the oscillation circuit and the temperature control circuit are provided in the first circuit device, and the first temperature sensor and the temperature adjustment element are provided in the second circuit device.

In the oscillator, the resonant element may be bonded to the second circuit device.

The oscillator may include a container accommodating the resonant element, the first circuit device, and the second circuit device, in which the second temperature sensor is provided in the first circuit device.

The oscillator may include a container accommodating the resonant element, the first circuit device, and the second circuit device, in which the second temperature sensor is provided outside the container.

An electronic apparatus according to still another aspect of the present disclosure includes: the oscillator according to the aspect; and a processing circuit, that operates on the basis of an output signal from the oscillator.

A vehicle according to still another aspect of the present disclosure includes: the oscillator according to the aspect; and a processing circuit that operates on the basis of an output signal from the oscillator.

### BRIEF DESCRIPTION OF THE DRAWINGS

FIG. 1 is a plan view of an oscillator according to the present embodiment.

FIG. 2 is a cross-sectional view of the oscillator according to the present embodiment.

FIG. 3 is a plan view of a container constituting the oscillator.

FIG. 4 is a cross-sectional view of the container constituting the oscillator.

FIG. 5 is a functional block view of the oscillator according to the present embodiment.

FIG. 6 is a view showing a specific configuration example of a second circuit device,

FIG. 7 is a view showing an example of a functional configuration of a temperature control circuit in a first embodiment.

FIG. 8 is a view showing an example of a relationship between an outside air temperature of an oscillator and a temperature of a resonant element.

FIG. 9 is a view showing an example of a relationship between a second temperature detection value and a temperature control correction value.

FIG. 10 is a view showing an example of a functional configuration of a temperature control circuit in a second embodiment.

FIG. 11 is a cross-sectional view of an oscillator according to a modification example.

FIG. 12 is a functional block view of an electronic apparatus of the present embodiment.

FIG. 13 is a view showing an example of an appearance of the electronic apparatus of the present embodiment.

FIG. 14 is a view showing an example of a vehicle according to the present embodiment.

### DESCRIPTION OF EXEMPLARY EMBODIMENTS

Hereinafter, a preferred embodiment of the present disclosure will be described in detail with reference to the accompanying drawings. Note that the embodiment to be described below does not unduly limit the contents of the disclosure described in the appended claims. In addition, all configurations to be described below are not limited to being essential constituent conditions of the disclosure.

### 1. Oscillator

### 1-1. First Embodiment

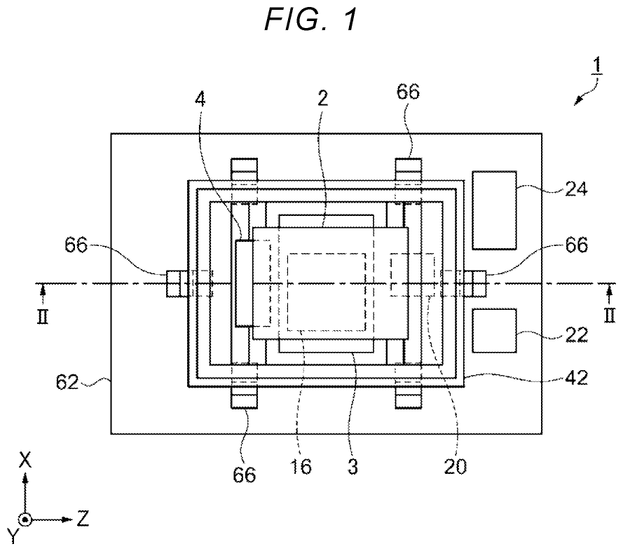

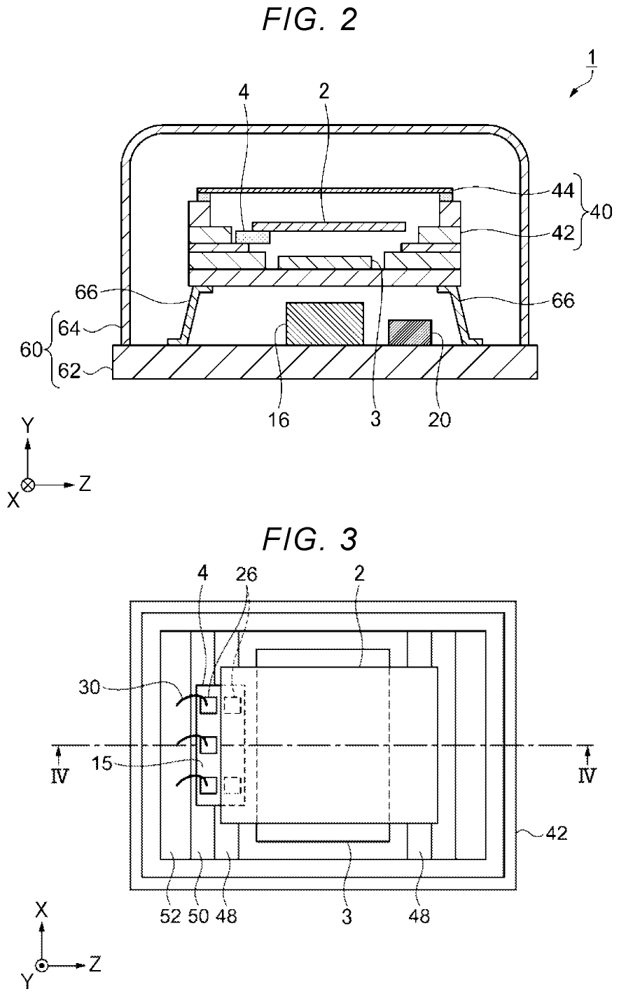

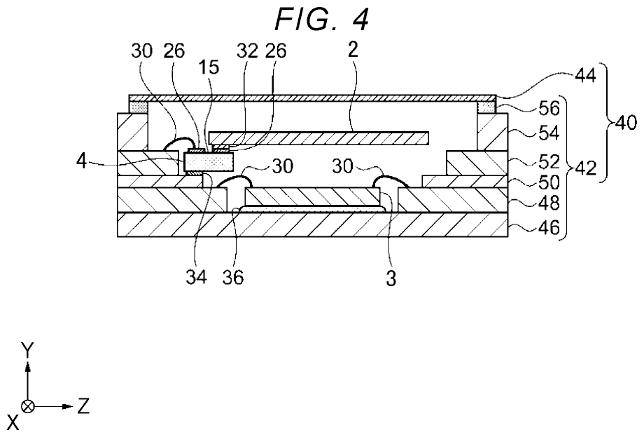

FIGS. 1 and 2 are views showing an example of a structure of an oscillator 1 according to the present embodiment. FIG. 1 is a plan view of the oscillator 1, and FIG. 2 is a cross-sectional view taken along line II-II shown in FIG. 1. FIGS. 3 and 4 are schematic configuration views of a container 40 constituting the oscillator 1. FIG. 3 is a plan view of the container 40 constituting the oscillator 1, and FIG. 4 is a cross-sectional view taken along line IV-IV shown in FIG. 3. In FIGS. 1 and 3, for the convenience of explaining the internal configuration of the oscillator 1 and the container 40, a state where a cover 64 and a lid member 44 are removed is illustrated. For convenience of explanation, an X axis, a Y axis, and a Z axis are illustrated as three axes orthogonal to each other. Further, for convenience of explanation, in the plan view when viewed from the Y axis direction, a surface in the +Y axis direction is described as an upper surface, and a surface in the −Y axis direction is described as a lower surface. Note that wiring patterns and electrode pads formed on the upper surface of a base substrate 62, the connection terminals formed on an outer surface of the container 40, and wiring patterns and electrode pads formed inside the container 40 are not shown.

As shown in FIGS. 1 and 2, the oscillator 1 includes the container 40 for accommodating therein a resonant element 2, a first circuit device 3 including an oscillation circuit, and a second circuit device 4 including a temperature adjustment element, and a circuit element 16 disposed on the upper surface of the base substrate 62 outside the container 40. The resonant element 2 may be, for example, an SC cut quartz crystal resonant element. The SC cut quartz crystal resonant element has excellent frequency stability because it has low external stress sensitivity.

On the upper surface of the base substrate 62 of the oscillator 1, the container 40 is disposed separately from the base substrate 62 via lead frames 66, and a plurality of circuit components 20, 22, and 24 such as capacitors and resistors are disposed. Furthermore, the container 40 and the circuit element 16 are covered with the cover 64 and accommodated in a container 60. Note that the inside of the container 60 is hermetically sealed in a reduced-pressure atmosphere such as a vacuum or an inert gas atmosphere such as nitrogen, argon, or helium.

The circuit element 16 or the circuit components 20, 22, and 24 for adjusting an oscillation circuit or the like included in the resonant element 2 or the first circuit device 3 are disposed outside the container 40 in which the second circuit device 4 is accommodated. Therefore, gas is not generated from a resin member constituting the circuit element 16, or solder, conductive adhesive, or the like which is a coupling member between the circuit element 16 or the circuit components 20, 22, and 24 and the container 40 due to a heat of the temperature adjustment element included in the second circuit device 4. Further, even when gas is generated, since the resonant element 2 is accommodated in the container 40, the oscillator 1 having high frequency stability can be obtained while maintaining stable frequency characteristics of the resonant element 2 without being affected by the gas.

As shown in FIGS. 3 and 4, the first circuit device 3, the second circuit device 4, and the resonant element 2 disposed on the upper surface of the second circuit device 4 are accommodated inside the container 40. Note that the inside of the container 40 is hermetically sealed in a reduced-pressure atmosphere such as a vacuum or an inert gas atmosphere such as nitrogen, argon, or helium.

The container 40 includes a package main body 42 and a lid member 44. As shown in FIG. 4, a first substrate 46, a second substrate 48, a third substrate 50, a fourth substrate 52, and a fifth substrate 54 are stacked to form the package main body 42. The second substrate 48, the third substrate 50, the fourth substrate 52, and the fifth substrate 54 are annular-form bodies from which the central portion is removed, and a sealing member 56 such as a seal ring or low melting point glass is formed on the periphery of the upper surface of the fifth substrate 54.

A recess portion for accommodating the first circuit device 3 is formed by the second substrate 48 and the third substrate 50, and a recess portion for accommodating the second circuit device 4 and the resonant element 2 is formed by the fourth substrate 52 and the fifth substrate 54.

The first circuit device 3 is bonded to a predetermined location on the upper surface of the first substrate 46 by a bonding member 36, and the first circuit device 3 is electrically coupled to an electrode pad (not shown) disposed on the upper surface of the second substrate 48 by a bonding wire 30.

The second circuit device 4 is bonded to a predetermined location on the upper surface of the third substrate 50 by a bonding member 34, and an electrode pad 26 formed on an active surface 15 which is the upper surface of the second circuit device 4 is electrically coupled to an electrode pad (not shown) disposed on the upper surface of the fourth substrate 52 by a bonding wire 30.

Since the first circuit device 3 and the second circuit device 4 are spaced apart from each other inside the container 40, the heat of the second circuit device 4 that heats the resonant element 2 is hardly transmitted directly to the first circuit device 3. Therefore, the characteristic deterioration of the oscillation circuit included in the first circuit device 3 due to the excessive heating can be controlled.

The resonant element 2 is disposed on the active surface 15 of the second circuit device 4. In the resonant element 2, the electrode pad 26 formed on the active surface 15 and an electrode pad (not shown) formed on a lower surface of the resonant element 2 are bonded to the second circuit device 4 via a bonding member 32 such as a metal bump or a conductive adhesive. Thereby, the resonant element 2 is supported by the second circuit device 4. An excitation electrode (not shown) formed on the upper and lower surfaces of the resonant element 2 and an electrode pad (not shown) formed on the lower surface of the resonant element 2 are electrically coupled to each other. The resonant element 2 and the second circuit device 4 may be coupled so that heat generated in the second circuit device 4 is transmitted to the resonant element 2. For example, the resonant element 2 and the second circuit device 4 are coupled by a non-conductive bonding member, and the resonant element 2 and the second circuit device 4 or the package main body 42 may be electrically coupled using a conductive member such as a bonding wire.

Therefore, since the resonant element 2 is disposed on the second circuit device 4, the heat of the second circuit device 4 can be transmitted to the resonant element 2 without loss, and the temperature control of the resonant element 2 can be further stabilized with low consumption.

In FIG. 1, the resonant element 2 has a rectangular shape in plan view when viewed from the Y axis direction, but the shape of the resonant element 2 is not limited to a rectangular shape, and may be, for example, a circular shape. The resonant element 2 is not limited to the SC cut quartz crystal resonant element, but may be an AT cut quartz crystal resonant element, a tuning fork type quartz crystal resonant element, a surface acoustic wave resonant element, other piezoelectric resonant elements, or a micro electro mechanical systems (MEMS) resonant element. Note that when an AT cut quartz crystal resonant element is used as the resonant element 2, a B-mode suppression circuit is not required, and thus the oscillator 1 can be reduced in size.

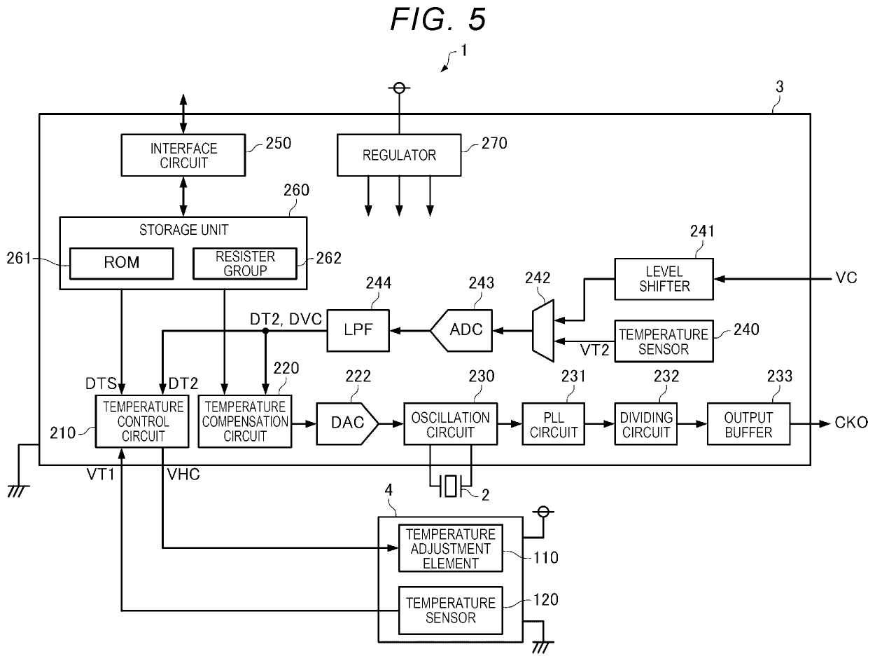

FIG. 5 is a functional block view of the oscillator 1 according to the present embodiment. As shown in FIG. 5, the oscillator 1 according to the present embodiment includes the resonant element 2, the first circuit device 3, and the second circuit device 4 that is different from the first circuit device.

The second circuit device 4 includes a temperature adjustment element 110 and a temperature sensor 120 that is a first temperature sensor.

The temperature adjustment element 110 is an element that adjusts the temperature of the resonant element 2, and is a heat generating element in the present embodiment. The heat generated by the temperature adjustment element 110 is controlled according to a temperature control signal VHC supplied from the first circuit device 3. As described above, since resonant element 2 is bonded to the second circuit device 4, the heat generated by the temperature adjustment element 110 is transmitted to the resonant element 2 so that the temperature of the resonant element 2 is adjusted so as to approach a desired constant temperature.

The temperature sensor 120 detects the temperature and outputs a first temperature detection signal VT1 having a voltage level in accordance with the detected temperature. As described above, since the resonant element 2 is bonded to the second circuit device 4 and the temperature sensor 120 is located in the vicinity of the resonant element 2, the temperature around the resonant element 2 can be detected. Further, since the temperature sensor 120 is located in the vicinity of the temperature adjustment element 110, it can be said that the temperature sensor 120 detects the temperature of the temperature adjustment element 110. The first temperature detection signal VT1 output from the temperature sensor 120 is supplied to the first circuit device 3.

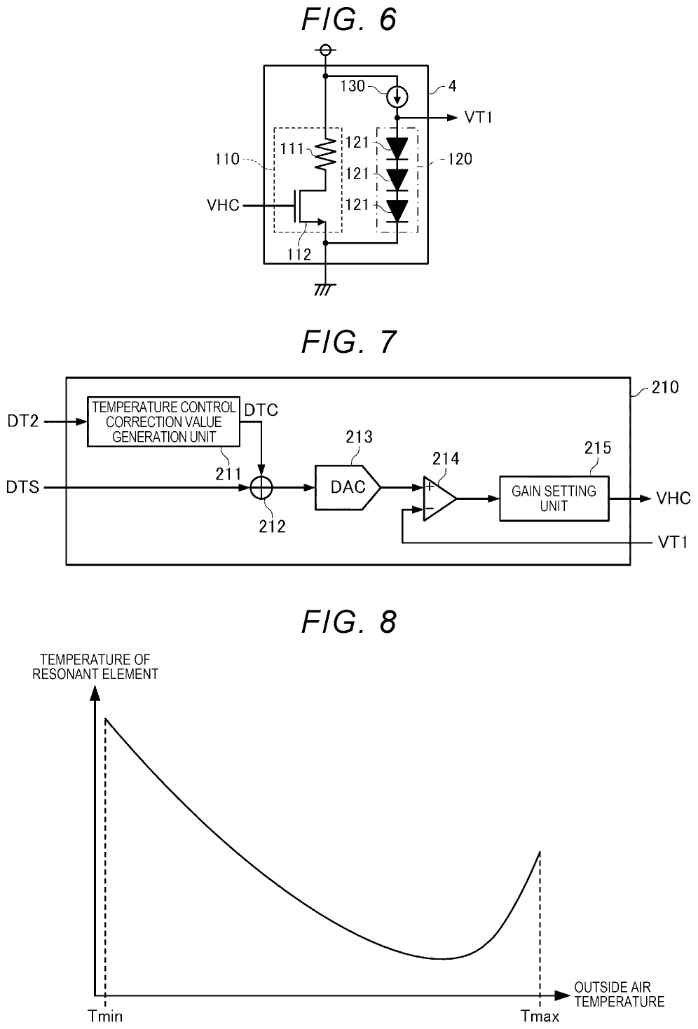

FIG. 6 is a view showing a specific configuration example of a second circuit device 4. In the example in FIG. 6, the temperature adjustment element 110 is configured so that a resistor 111 and a MOS transistor 112 are connected in series between a power source and a ground, and the temperature control signal VHC is input to a gate of the MOS transistor 112. The current flowing through the resistor 111 is controlled by the temperature control signal VHC, and thereby the amount of heat generated by the resistor 111 is controlled.

Further, the temperature sensor 120 is configured so that one or a plurality of diodes 121 are connected in series in the forward direction between the power source and the ground. A constant current is supplied to the temperature sensor 120 from a constant current source 130, thereby a constant forward direction current flows through the diode 121. When the constant forward direction current flows through the diode 121, the voltage at both ends the diode 121 is changed substantially linearly with respect to the temperature change, so that, for example, an anode voltage of the diode 121 becomes a linear voltage with respect to the temperature. Therefore, a signal generated at the anode of the diode 121 can be used as the first temperature detection signal VT1.

Returning to FIG. 5, the first circuit device 3 includes a temperature control circuit 210, a temperature compensation circuit 220, a D/A conversion circuit 222, an oscillation circuit 230, a phase locked loop (PLL) circuit 231, a dividing circuit 232, an output buffer. 233, a temperature sensor 240 that is a second temperature sensor, a level shifter 241, a selector 242, an A/D conversion circuit 243, a low pass filter 244, an interface circuit 250, a storage unit 260, and a regulator 270.

The temperature control circuit 210 generates the temperature control signal VHC for controlling the temperature adjustment element 110 on the basis of a temperature set value DTS of the resonant element 2, the first temperature detection value detected by the temperature sensor 120, and a temperature control correction value DTC that is non-linear with respect to a second temperature detection value DT2 detected by the temperature sensor 240. In the present embodiment, the temperature set value DTS is a set value of the target temperature of the resonant element 2 and is stored in a read only memory (ROM) 261 of the storage unit 260. When the power source of the oscillator 1 is turned on, the temperature set value DTS is transferred from the ROM 261 to a predetermined register included in a register group 262 and stored, and the temperature set value DTS stored in the register is supplied to the temperature control correction value generation unit 211.

In the present embodiment, the first temperature detection value is a voltage value of the first temperature detection signal VT1 output from the temperature sensor 120. The second temperature detection, value DT2 is generated on the basis of an output signal of the temperature sensor 240 by the selector 242, the A/D conversion circuit 243, and the low pass filter 244. Further, a temperature control correction value DTC (not shown in FIG. 5) is generated by the temperature control circuit 210 on the basis of the second temperature detection value DT2. Note that a specific configuration example of the temperature control circuit 210 will be described later.

The temperature compensation circuit 220 temperature compensates the frequency of the oscillation circuit 230 on the basis of the second detected temperature value DT2. In the present embodiment, the temperature compensation circuit 220 generates a temperature compensation value that is a digital signal for a temperature compensation so that the frequency of the oscillation circuit 230 becomes a desired frequency in accordance with a frequency control value DVC on the basis of the second temperature detection value DT2. For example, in the inspection process at the time of manufacturing the oscillator 1, the temperature compensation circuit 220 generates temperature compensation data for generating a temperature compensation value that is an approximately opposite characteristic to the frequency-temperature characteristics of the resonant element 2 and stores the temperature compensation data in the ROM 261 of the storage unit 260. When the power source of the oscillator 1 is turned on, the temperature compensation data is transferred from the ROM 261 to a predetermined register included in the register group 262 and stored, and the temperature compensation circuit 220 generates a temperature compensation value on the basis of the temperature compensation data stored in the register, the second temperature detection value DT2, and the frequency control value DVC.

The D/A conversion circuit 222 converts the temperature compensation value generated by the temperature compensation circuit 220 into a temperature compensation voltage that is an analog signal, and supplies the voltage to the oscillation circuit 230.

The oscillation circuit 230 is electrically coupled to both ends of the resonant element 2, and is a circuit that oscillates the resonant element 2 by amplifying the output signal of the resonant element 2 and feeding the amplified signal back to the resonant element 2. For example, the oscillation circuit 230 may be an oscillation circuit using an inverter as an amplifying element, or maybe an oscillation circuit using a bipolar transistor as an amplifying element. In the present embodiment, the oscillation circuit 230 oscillates the resonant element 2 at a frequency in accordance with the temperature compensation voltage supplied from the D/A conversion circuit 222. Specifically, the oscillation circuit 230 includes a variable capacitance element (not shown) that serves as a load capacitance of the resonant element 2, and a temperature compensation voltage is applied to the variable capacitance element to obtain a load capacitance value in accordance with the temperature compensation voltage, thereby the frequency of the oscillation signal output from the oscillation circuit 230 is temperature compensated.

The PLL circuit 231 multiplies the frequency of the oscillation signal output from the oscillation circuit 230.

The dividing circuit 232 divides the oscillation signal output from the PLL circuit 231.

The output buffer 233 performs buffering the oscillation signal output from the dividing circuit 232 and outputs the oscillation signal as an oscillation signal CKO to the outside of the first circuit device 3. This oscillation signal CKO becomes an output signal of the oscillator 1.

The temperature sensor 240 detects the temperature and outputs a second temperature detection signal VT2 having a voltage level in accordance with the detected temperature. As described above, the first circuit device 3 is bonded to the upper surface of the first substrate 46, and the temperature sensor 240 is provided at a location farther from the resonant element 2 or the temperature adjustment element 110 than the temperature sensor 120. Therefore, the temperature sensor 120 detects the internal temperature of the container 40 at a location away from the resonant element 2 or the temperature adjustment element 110. Further, the heat of the outside air is transmitted to the container 40 through the lead frame 66. Therefore, regarding the temperature, when the outside air temperature of the oscillator is changed within a predetermined range, the temperature detected by the temperature sensor 120 provided in the vicinity of the temperature adjustment element 110 hardly changes but the temperature detected by the temperature sensor 240 changes within the predetermined range.

The level shifter 241 converts a frequency control signal VC supplied from the outside of the oscillator 1 into a desired voltage level.

The selector 242 selects and outputs either one of the frequency control signal VC output from the level shifter 241 or the second temperature detection signal VT2 output from the temperature sensor 240. In the present embodiment, the selector 242 selects and outputs the frequency control signal VC and the second temperature detection signal VT2 in a time division manner. However, for example, in the inspection process at the time of manufacturing the oscillator 1, when a selection value for selecting either one of the frequency control signal VC or the second temperature detection signal VT2 is stored in the ROM 261 of the storage unit 260 in accordance with the specifications of the oscillator 1 and the power source of the oscillator 1 is turned on, the selection value may be tram erred from the ROM 261 to a predetermined register included in the register group 262 and stored, and the selection value stored in the register may be supplied to the selector 242.

The A/D conversion circuit 243 converts the frequency control signal VC and the second temperature detection signal VT2, which are analog signals output from the selector 242 in a time division manner, into the frequency control value DVC and the second temperature detection value DT2, which are digital signals, respectively.

The law pass filter 244 is a digital filter that performs low pass processing on the frequency control value DVC and the second temperature detection value DT2 that are output from the A/D conversion circuit 243 in a time division manner, and reduces the strength of the high frequency noise signal.

The interface circuit 250 is a circuit for performing data communication with an external device (not shown) connected to the oscillator 1. The interface circuit 250 may be, for example, an interface circuit corresponding to an inter-integrated circuit (I²C) bus or an interface circuit corresponding to a serial peripheral interface (SRI) bus.

The storage unit 260 includes the RCN 261 that is a non-volatile memory and the register group 262 that is a volatile memory. In the inspection process at the time of manufacturing the oscillator 1, the external device writes various data for controlling the operation of each circuit included in the oscillator 1 to the various registers included in the register group 262 via the interface circuit 250 and adjusts each circuit. Further, the external device stores various determined optimum data in the ROM 261 via the interface circuit 250. When the power source of the oscillator 1 is turned on, various data stored in the ROM 261 is transferred and stored in various registers included in the register group 262, and the various data stored in the various registers are supplied to each circuit.

The regulator 270 generates a power voltage or a reference voltage for each circuit included in the first circuit device 3 on the basis of a power voltage supplied from the outside of the first circuit device

FIG. 7 is a view showing an example of a functional configuration of the temperature control circuit 210. As shown in FIG. 7, the temperature control circuit 210 includes a temperature control correction value generation unit 211, an addition unit 212, a D/A conversion unit 213, a comparison unit 214, and a gain setting unit 215.

The temperature control correction value generation unit 211 generates the temperature control correction value DTC that is non-linear with respect to the second temperature detection value DT2.

The addition unit 212 adds the temperature set value DTS stored in a predetermined register included in the register group 262 of the storage unit 260 and the temperature control correction value DTC generated by the temperature control correction value generation unit 211.

The D/A conversion unit 213 converts a value of the addition result by the addition unit 212 into an analog signal and supplies the analog signal to the comparison unit 214.

The comparison unit 214 compares the voltage of the analog signal supplied from the D/A conversion unit 213 with the voltage of the first temperature detection signal VT1 output from the temperature sensor 120, and outputs a comparison result signal. In the present embodiment, the comparison unit 214 outputs a low level signal when the voltage of the first temperature detection signal VT1 is higher than the voltage of the analog signal supplied from the D/A conversion unit 213. Further, the comparison unit 214 outputs a high level signal when the voltage of the first temperature detection signal VT1 is lower than the voltage of the analog signal supplied from the D/A conversion unit 213.

The gain setting unit 215 generates the temperature control signal VC by multiplying the voltage of the output signal of the comparison unit 214 by a predetermined value. The temperature control signal VHC is supplied to the temperature adjustment element 110 of the second circuit device 4.

Thus, in the present embodiment, the temperature control circuit 210 generates the temperature control signal VHC by comparing a value obtained by adding the temperature set value DTS and the temperature control correction value DTC with the first temperature detection value. When the temperature control signal VHC is at a high level, that is, when the temperature detected by the temperature sensor 120 is lower than the target temperature, for example, the current flows through the resistor 111 in FIG. 6 and heat is generated, and the temperature of the resonant element 2 is increased. On the other hand, when the temperature control signal VHC is at a low level, that is, when the temperature detected by the temperature sensor 120 is higher than the target temperature, for example, the current does not flow through the resistor 111 in FIG. 6 and heat generation is stopped, and the temperature of the resonant element 2 is decreased. Thereby, the temperature of the resonant element 2 is controlled so as to approach near the target temperature.

In the present embodiment, as described above, the temperature adjustment element 110 and the temperature sensor 120 are both provided in the second circuit device 4. Therefore, when a large current flows through the temperature adjustment element 110, the ground potential of the second circuit device 4 fluctuates unevenly depending on the location, the voltage value of the first temperature detection signal VT1 output from the temperature sensor 120 or the voltage value of the temperature control signal VHC fluctuates. As a result, when the temperature control correction value DTC is always zero regardless of the second temperature detection value DT2, the temperature of the resonant element 2 is changed in a non-linear manner with respect to the outside air temperature.

FIG. 8 is view showing an example of a relationship between the outside air temperature of the oscillator 1 and the temperature of the resonant element 2 when the temperature control correction value DTC is always zero regardless of the second temperature detection value DT2. As shown in FIG. 8, the temperature of the resonant element 2 is changed in a non-linear manner with respect to the outside air temperature, and can be approximated by a second-order or higher polynomial having the outside air temperature as a variable. In other words, it is possible to correct the temperature of the resonant element 2 that fluctuates depending on the outside air temperature by using a second-order or higher polynomial that approximates a characteristic opposite to the temperature characteristic of the resonant element 2.

In the present embodiment, the temperature control correction value generation unit 211 generates the temperature control correction value DTC represented by a second-order or higher polynomial having the second temperature detection value DT2 that is changed according to the outside air temperature as a variable, as in the following Expression (1). In the Expression (1), ‘n’ is an integer of one or more, and aₙ to a₀ are coefficient values of n-th to 0-th order terms.

DTC=aₙ·DT2ₙ+aₙ₋₁·DT2ⁿ⁻¹+ . . . +a₁·DT2+a₀ (1)

For example, the coefficient values aₙ to a₀ are calculated in the inspection process at the time of manufacturing the oscillator 1 and stored in the ROM 261 of the storage unit 260. When the power source of the oscillator 1 is turned on, the coefficient values aₙ to a₀ are transferred from the ROM 261 to a predetermined register included in the register group 262 and stored, and the coefficient values aₙ to a₀ stored in the register may be supplied to the temperature control correction value generation unit 211.

After the power source of the oscillator 1 is turned on, the temperature adjustment element 110 generates heat, and the temperature of the resonant element 2 reaches near the target temperature. After the temperature of the resonant element 2 reaches near the target temperature, the temperature detected by the temperature sensor 240 is changed in a linear manner in the first range with respect to the outside air temperature, and the temperature of the resonant element 2 fluctuates in a non-linear manner according to the outside air temperature. Therefore, the temperature of the resonant element 2 is effectively corrected using the temperature control correction value DTC shown in Expression (1). In contrast to this, during a period from when the power source of the oscillator 1 is turned on until the temperature of the resonant element 2 reaches near the target temperature, even when the outside air temperature is constant, the temperature detected by the temperature sensor 240 is increased or decreased toward the above-described first range. Therefore, during the period, when the temperature of the resonant element 2 is corrected using the temperature control correction value DTC shown in Expression (1), an excessive correction is performed, and the time required for the temperature of the resonant element 2 to stabilize near the target temperature may increase.

Therefore, the temperature control correction value DTC is non-linear with respect to the second temperature detection value DT2 in the first range of the second temperature detection value DT2, and may be a fixed value regardless of the second temperature detection value DT2 in at least one of a lower limit or less of the first range and the upper limit or more of the first range of the second temperature detection value DT2.

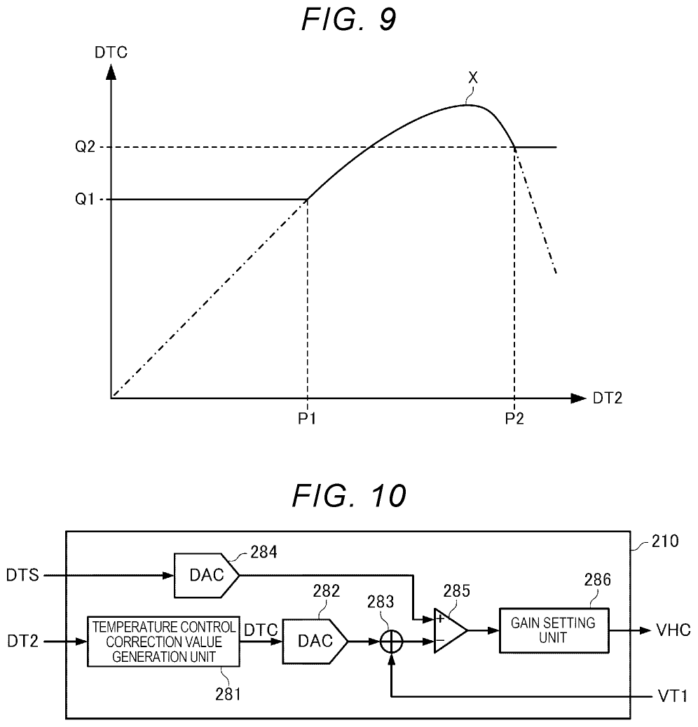

FIG. 9 is a view showing an example of a relationship between the second temperature detection value DT2 and the temperature control correction value DTC in the example in FIG. 8. In the example in FIG. 9, the range from P1 or more and P2 or less is the first range, and in a state where the temperature of the resonant element 2 is near the target temperature, the second temperature detection value DT2 is approximately P1 when the outside air temperature is Tmin, and is approximately P2 when the outside air temperature is Tmax. That is, in a state where the temperature of the resonant element 2 is near the target temperature, when the outside air temperature is changed in the range of Tmin or more and Tmax or less, the second temperature detection value DT2 is changed in the first range of P1 or more and P2 or less.

In the first range of the second temperature detection value DT2, the temperature control correction value DTC is changed at a curve opposite to the temperature change curve of the resonant element 2 when the outside air temperature shown in FIG. 8 is changed in the range of Tmin to Tmax, for example, at a curve X approximated by a second-order or higher polynomial of the second temperature detection value DT2. Thereby, in a state where the temperature of the resonant element 2 is near the target temperature, when the outside air temperature is changed in the range of Tmin to Tmax, the temperature of the resonant element 2 is corrected so as to be maintained at a temperature near the target temperature.

On the other hand, in the lower limit value P1 or less of the first range of the second temperature detection value DT2, the temperature control correction value DTC is a fixed value Q1 regardless of the second temperature detection value DT2. Further, in the upper limit value P2 or more of the first range of the second temperature detection value DT2, the temperature control correction value DTC is a fixed value Q2 regardless of the second temperature detection value DT2. For example, Q1 may be a value of the temperature control correction value DTC at the lower limit value P1 of the first range, and Q2 may be a value of the temperature control correction value DTC at the upper limit value P2 of the first range so that the temperature control correction value DTC is not discontinuous at the lower limit value P1 and the upper limit value P2 of the first range.

In this way, the temperature control correction value DTC is the fixed value Q1 at the lower limit value P1 or less of the first range, and is the fixed value Q2 at the upper limit value P2 or more of the first range. Further, the temperature control correction value DTC is not changed at a curve indicated by a one-dot chain line in FIG. 9, that is, a curve obtained by extending the curve X. Thereby, the excessive correction is not performed until the temperature of the resonant element 2 reaches near the target temperature, and the time required for the temperature of the resonant element 2 to stabilize at a temperature near the target temperature can be shortened.

In the example in FIG. 9, the temperature control correction value DTC is a fixed value in both the lower limit value P1 or less and the upper limit value P2 or more of the first range of the second temperature detection value DT2, but may be a fixed value in only one of the lower limit value P1 or less or the upper limit value P2 or more of the first range of the second temperature detection value DT2 according to the relationship between the target temperature of the resonant element 2 and the outside air temperature. For example, when the upper limit value P2 of the first range is close to Tmax, the temperature control correction value DTC may be set to the fixed value Q2 only at the upper limit value P2 or more, and when the lower limit value P1 of the first range is close to Tmin, the temperature control correction value DTC maybe set to the fixed value Q1 only at the lower limit value P1 or less of the first range.

As described above, in the oscillator 1 according to the first embodiment and in the first circuit device 3, the temperature control circuit 210 generates the temperature control signal VHC for controlling the temperature adjustment element 110 on the basis of the temperature set value DTS of the resonant element 2, the voltage value of the first temperature detection signal VT1 that is the first temperature detection value detected by the temperature sensor 120, and the temperature control correction value DTC that is non-linear with respect to the second temperature detection value DT2 detected by the temperature sensor 240. Specifically, the temperature control circuit 210 generates the temperature control signal VHC by comparing a value obtained by adding the temperature set value DTS and the temperature control correction value DTC with the first temperature detection value. That is, since the temperature control correction value DTC is non-linear with respect to the second temperature detection value DT2 that is changed following the change in the outside air temperature, even when the temperature of the resonant element 2 is changed in a non-linear manner with respect to the change in the outside air temperature, the temperature of the resonant element 2 can be approached near the target temperature. Therefore, according to the circuit device 3 in the first embodiment, it is possible to control the temperature of the resonant element 2 with higher accuracy as compared with the related art with respect to fluctuations in the outside air temperature. Further, according to the oscillator 1 in the first embodiment, it is possible to generate the oscillation signal CKO with higher frequency accuracy as compared with the related art with respect to the fluctuation of the outside air temperature.

In the oscillator 1 according to the first embodiment, the temperature control correction value DTC is non-linear with respect to the second temperature detection value DT2 in the first range of the second temperature detection value DT2, and is a fixed value regardless of the second temperature detection value DT2 in at least one of a lower limit or less of the first range and the upper limit or more of the first range of the second temperature detection value DT2. Therefore, according to the circuit device 3 in the first embodiment or the oscillator 1 in the first embodiment, the excessive correction is not performed until the temperature of the resonant element 2 reaches near the target temperature, and the time required for the temperature of the resonant element 2 to stabilize at a temperature near the target temperature can be shortened.

In the oscillator 1 according to the first embodiment, in the first circuit device 3, the temperature compensation circuit 220 temperature compensates the frequency of the oscillation circuit 230 on the basis of the second temperature detection value DT2. That is, the second temperature detection value DT2 is used for both temperature control of the resonant element 2 and temperature compensation of the oscillation signal CKO. Therefore, according to the circuit device 3 in the first embodiment or the oscillator 1 in the first embodiment, the circuit size can be reduced by using the temperature sensor 240 along with the temperature control of the resonant element 2 and temperature compensation of the oscillation signal CKQ.

In the oscillator 1 according to the first embodiment, the temperature sensor 120 and the temperature adjustment element 110 are provided in the second circuit device 4, and the resonant element 2 is bonded to the second circuit device 4. Therefore, according to the oscillator 1 in the first embodiment, since the temperature sensor 120 that detects the temperature around the resonant element 2 and the temperature adjustment element 110 that adjusts the temperature of the resonant element 2 are provided at locations very close to the resonant element 2, the temperature control of the resonant element 2 can be performed with high accuracy, and the time required for the temperature of the resonant element 2 to stabilize at a temperature near the target temperature can be shortened. Further, since the temperature sensor 120 and the temperature adjustment element 110 are integrated, it is advantageous for downsizing the oscillator 1.

In the oscillator 1 according to the first embodiment, the resonant element 2, the first circuit device 3, and the second circuit device 4 are accommodated in the container 40, and the temperature sensor 240 is provided in the first circuit device 3. Therefore, according to the oscillator 1 of the first embodiment, the temperature sensor 240 is not easily affected by a sudden change in the outside air temperature, and the possibility that the accuracy of temperature control of the resonant element 2 is lowered due to the sudden change in the outside air temperature is reduced.

### 1-2. Second embodiment

Hereinafter, for the oscillator 1 in a second embodiment, the same components as those of the first embodiment are given the same reference numerals, the same descriptions as those of the first embodiment are omitted or simplified, and the contents different from the first embodiment will be mainly described. In the oscillator 1 according to the second embodiment, similar to the oscillator 1 according to the first embodiment, the temperature control circuit 210 included in the first circuit device 3 generates the temperature control signal VHC for controlling the temperature adjustment element 110 on the basis of the temperature set value of the resonant element 2, the first temperature detection value detected by the temperature sensor 120, and the temperature control correction value that is non-linear with respect to the second temperature detection value detected by the temperature sensor 240. However, the configuration of the temperature control circuit 210 is different from that of the first embodiment.

FIG. 10 is a view showing an example of a functional configuration of the temperature control circuit 210 in the second embodiment. As shown in FIG. 10, the temperature control circuit 210 includes a temperature control correction value generation unit 281, a D/A conversion unit 282, an addition unit 263, a D/A conversion unit 284, a comparison unit 285, and a gain setting unit 286.

The temperature control correction value generation unit 281 generates a temperature control correction value DTC that is non-linear with respect to the second temperature detection value DT2.

The D/A conversion unit 282 converts the temperature control correction value DTC generated by the temperature control correction value generation unit 281 into an analog signal and supplies the analog signal to the addition unit 283.

The addition unit 283 adds the voltage of the analog signal supplied from the D/A conversion unit 282 and the voltage of the first temperature detection signal VT1 output from the temperature sensor 120, and supplies the added voltage to the comparison unit 285.

The D/A conversion unit 284 converts the temperature set value DTS stored in a predetermined register included in the register group 262 of the storage unit 260 into an analog signal and supplies the analog signal to the comparison unit 285.

The comparison unit 285 compares the voltage of the analog signal supplied from the D/A conversion unit 284 with the voltage supplied from the addition unit 283, and outputs a comparison result signal. In the present embodiment, the comparison unit 285 outputs a low level signal when the voltage supplied from the addition unit 283 is higher than the voltage of the analog signal supplied from the D/A conversion unit 284. Further, the comparison unit 285 outputs a high level signal when the voltage supplied from the addition unit 283 is lower than the voltage of the analog signal supplied from the D/A conversion unit 284.

The gain setting unit 286 generates a temperature control signal VHC by multiplying the voltage of the output signal of the comparison unit 285 by a predetermined value. The temperature control signal VHC is supplied to the temperature adjustment element 110 of the second circuit device 4.

Thus, in the present embodiment, the temperature control circuit 210 generates the temperature control signal VHC by comparing a value obtained by adding the first temperature detection value to the temperature control correction value with the temperature set value. The first temperature detection value is a voltage value of the first temperature detection signal VT1 output from the temperature sensor 120. The temperature control correction value is a voltage value of an analog signal obtained by converting the temperature control correction value DTC by the D/A conversion unit 282. Further, the temperature set value is a voltage value of an analog signal obtained by converting the temperature set value DTS by the D/A conversion unit 284.

When the temperature control signal VHC is at a high level, that is, when the temperature detected by the temperature sensor 120 is lower than the target temperature, for example, the current flows through the resistor 111 in FIG. 6 and heat is generated, and the temperature of the resonant element 2 is increased. On the other hand, when the temperature control signal VHC is at a low level, that is, when the temperature detected by the temperature sensor 120 is higher than the target temperature, for example, the current does not flow through the resistor 111 in FIG. 6 and heat generation is stopped, and the temperature of the resonant element 2 is decreased. Thereby, the temperature of the resonant element 2 is controlled so as to approach near the target temperature.

Note that since the other configuration of the oscillator 1 according to the second embodiment is the same as that of the oscillator 1 according to the first embodiment, the description is omitted.

As described above, in the oscillator 1 according to the second embodiment, since the temperature control correction value DTC is non-linear with respect to the second temperature detection value DT2 that is changed following the change in the outside air temperature, even when the temperature of the resonant element 2 is changed in a non-linear manner with respect to the change in the outside air temperature, the temperature of the resonant element 2 can be approached near the target temperature. Therefore, according to the circuit device the second embodiment, it is possible to control the temperature of the resonant element 2 with higher accuracy as compared with the related art with respect to fluctuations in the outside air temperature. Further, according to the oscillator 1 in the second embodiment, it is possible to generate the oscillation signal CKO with higher frequency accuracy as compared with the related art with respect to the fluctuation of the outside air temperature.

In addition, the circuit device 3 in the second embodiment and the oscillator 1 in the second embodiment can achieve the same effects as the circuit device 3 in the first embodiment and the oscillator 1 in the first embodiment, respectively.

### 1-3. Modification Example

In each of the above embodiments, the temperature adjustment element 110 for maintaining the temperature of the resonant element 2 near the target temperature is included in the second circuit device 4 accommodated in the container 40, but may be provided inside the container 40 at a location close to the resonant element 2 outside the second circuit device 4. Alternatively, the temperature adjustment element 110 may be provided outside the container 40, and may be an element such as a power transistor provided on the lower surface or the like of the container 40, for example.

The temperature sensor 120 for detecting the temperature around the resonant element 2 is included in the second circuit device 4 accommodated in the container 40 in the above embodiments, but may be provided inside the container 40 at a location close to the resonant element 2 outside the second circuit device 4.

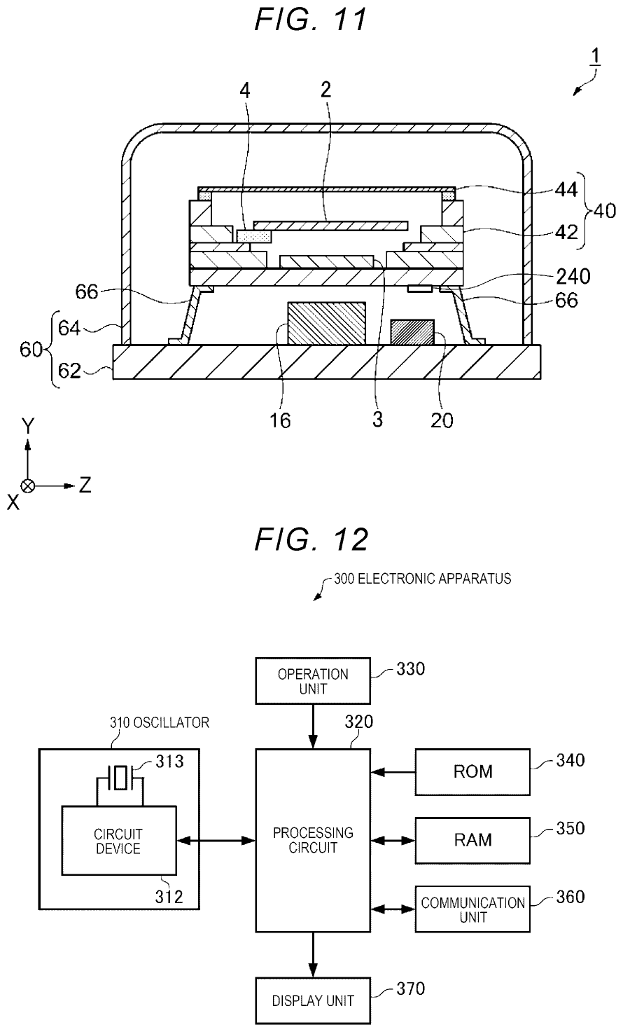

Further, in each of the above embodiments, the temperature sensor 240, in which the temperature to be detected with respect to the change in the outside temperature of the oscillator 1 is changed, is included in the first circuit device 3 accommodated in the container 40, but may be provided at a location outside the first circuit device 3 and farther from the resonant element 2 or the temperature adjustment element 110 than the temperature sensor 120. For example, the temperature sensor 240 may be provided outside the first circuit device 3 inside the container 40, or may be provided outside the container 40. FIG. 11 is a view showing an example in which the temperature sensor 240 is provided outside the first circuit device 3. FIG. 11 is a view corresponding to the cross-sectional view taken along line II-II shown in FIG. 1. In the example in FIG. 11, the temperature sensor 240 is provided near the lead frame 66 on the lower surface of the container 40. Since the heat of the outside air is transmitted to the container 40 via the lead frame 66, the temperature around the lead frame 66 is easily affected by the outside air temperature. Therefore, the dynamic range, which is the temperature range detected by the temperature sensor 240, becomes wider, and the temperature control accuracy of the resonant element 2 can be improved. In general, as the temperature sensor 240 is farther from the temperature adjustment element 110 and closer to the outside air, the dynamic range of the temperature sensor 240 becomes wider, but when the temperature sensor 240 is too close to the outside air, the instantaneous effect of the outside air such as strong wind or snowfall may be captured, and the temperature control accuracy of the resonant element 2 may be reduced. Therefore, the temperature sensor 240 may be provided at a location having a certain amount of heat resistance with respect to the outside air.

Further, in each of the above embodiments, the temperature control correction value DTC is represented by a second-order or higher polynomial having the second temperature detection value DT2 as a variable, and in the inspection process at the time of manufacturing the oscillator 1, the coefficient value of the polynomial is calculated, but when the variation in characteristics of each oscillator 1 is small, the coefficient value may be determined at a design stage. In this case, since it is not necessary to calculate the coefficient value in the inspection process, the cost of the oscillator 1 can be reduced.

In each of the embodiments described above, the temperature control correction value DTC is expressed by a second-order or higher polynomial having the second temperature detection value DT2 as a variable, but as long as the temperature control correction value DTC is non-linear with respect to the second temperature detection value DT2, the temperature control correction value DTC may not be expressed by a second-order or higher polynomial having the second temperature detection value DT2 as a variable. For example, table information defining the correspondence between the second temperature detection value DT2 and the temperature control correction value DTC is stored in the ROM 261 of the storage unit 260, and the temperature control correction value generation unit 211 may generate the temperature control correction value DTC that is non-linear with respect to the second temperature detection value DT2 on the basis of the table information.

In each of the above embodiments, the temperature control circuit 210 generates the temperature control correction value DTC on the basis of the second temperature detection value DT2 generated from the second temperature detection signal VT2 output from the temperature sensor 240 but the method for generating the temperature control correction value DTC is not limited to this. For example, the oscillator 1 may generate the second temperature detection value DT2 on the basis of the current value flowing through the resistor 111 of the temperature adjustment element 110 shown in. FIG. 6, and the temperature control circuit 210 may generate the temperature control correction value DTC on the basis of the second temperature detection value DT2.

In each of the above embodiments, although the frequency of the oscillation signal CKO is temperature compensated by adjusting the capacitance value of the variable capacitance element included in the oscillation circuit 230 in accordance with the temperature compensation voltage supplied from the D/A conversion circuit 222, the temperature compensation method is not limited to this. For example, the oscillation circuit 230 has a capacitance array, and by selecting the capacitance value of the capacitance array on the basis of the temperature compensation value generated by the temperature compensation circuit 220, the frequency of the oscillation signal CKO may be temperature compensated. Further, for example, by replacing the PLL circuit 231 with a fractional N type PLL circuit d adjusting the division ratio of the fractional N type PLL circuit on the basis of the temperature compensation value generated by the temperature compensation circuit 220, the frequency of the oscillation signal CKO may be temperature compensated. The D/A conversion circuit 222 is not necessary in these modification examples.

In each of the embodiments described above, the temperature adjustment element 110 is a heat generating element including the resistor 111 and the MOS transistor 112, but may be a heat generating element such as a power transistor, for example. The temperature adjustment element 110 may be any element that can adjust the temperature of the resonant element 2, and may be a heat absorbing element such as a Peltier element depending on the relationship between the target temperature of the resonant element 2 and the outside air temperature.

Further, in each of the embodiments described above, in addition to the temperature control function that adjusts the temperature of the resonant element 2 near the target temperature, the oscillator 1 is an oscillator having a temperature compensation function based on the second temperature detection value DT2 and a frequency control function based on the frequency control value DVC, but may be an oscillator that does not have at least one of the temperature compensation function and the frequency control function.

### 2. Electronic Apparatus

FIG. 12 is a functional block view showing an example of a configuration of an electronic apparatus according to the present embodiment.

An electronic apparatus 300 of the present embodiment is configured to include an oscillator 310, a processing circuit 320, an operation unit 330, a read only memory (ROM) 340, a random access memory (RAN) 350, a communication unit 360, and a display unit 370. Note that the electronic apparatus of the present embodiment may be configured such that some of the components illustrated in FIG. 12 are omitted or changed, or other components are added thereto.

The oscillator 310 includes a circuit device 312 and a resonant element 313. The circuit device 312 oscillates the resonant element 313 to generate an oscillation signal. The oscillation signal is output from an external terminal of the oscillator 310 to the processing circuit 320.

The processing circuit 320 operates on the basis of an output signal from the oscillator 310. For example, the processing circuit 320 performs various calculation processes or control processes by using the oscillation signal input from the oscillator 310 as a clock signal in accordance with programs stored in the ROM 340 and the like. Specifically, the processing circuit 320 performs various processes according to an operation signal from the operation unit 330, a process of controlling the communication unit 360 in order to perform data communication with an external device, a process of transmitting display signals for displaying various pieces of information on the display unit 370, and the like.

The operation unit 330 is an input device configured with operation keys, button switches, and the like, and outputs an operation signal according to a user's operation to the processing circuit 320.

The ROM 340 is a storage unit that stores programs, data, and the like for performing various calculation processes and control processes by the processing circuit 320.

The RAM 350 is a storage unit which is used as a work area of the processing circuit 320, and temporarily stores programs and data read out from the ROM 340, data input from the operation unit 330, results of computation executed by the processing circuit 320 in accordance with various programs, and the like.

The communication unit 360 performs various control processes for establishing data communication between the processing circuit 320 and an external device.

The display unit 370 is a display device configured with a liquid crystal display (LCD) and the like, and displays various pieces of information on the basis of the display signals input from the processing circuit 320. A touch panel functioning as the operation unit 330 may be provided in the display unit 370.

By applying, for example, the oscillator 1 of each embodiment described above as the oscillator 310, it is possible to generate an oscillation signal with higher frequency accuracy as compared with the related art with respect to fluctuations in the outside air temperature, thereby a highly reliable electronic apparatus can be realized.

Various electronic apparatuses are conceived as the electronic apparatus 300, and may be, for example, a personal computer such as a mobile type personal computer, a laptop type personal computer, and a tablet type personal computer, a mobile terminal such as a smartphone or a mobile phone, a digital camera, an ink jet type ejection device such as an ink jet printer, a storage area network apparatus such as a router or a switch, a local area network apparatus, a mobile terminal base station apparatus, a television, a video camera, a video recorder, a car navigation device, a real-time clock device, a pager, an electronic organizer, an electronic dictionary, an electronic calculator, an electronic gaming machine, a gaming controller, a word processor, a workstation, a videophone, a security television monitor, electronic binoculars, a POS terminal, a medical apparatus such as an electronic thermometer, a sphygmomanometer, a blood glucose monitoring system, an electrocardiographic apparatus, an ultrasonic diagnostic apparatus, an electronic endoscope, a fish-finder, various measurement apparatuses, meters and gauges such as meters and gauges of vehicles, aircrafts, and ships, a flight simulator, a head mounted display, a motion tracer, a motion tracker, a motion controller, a pedestrian dead reckoning (PDR) apparatus, and the like.

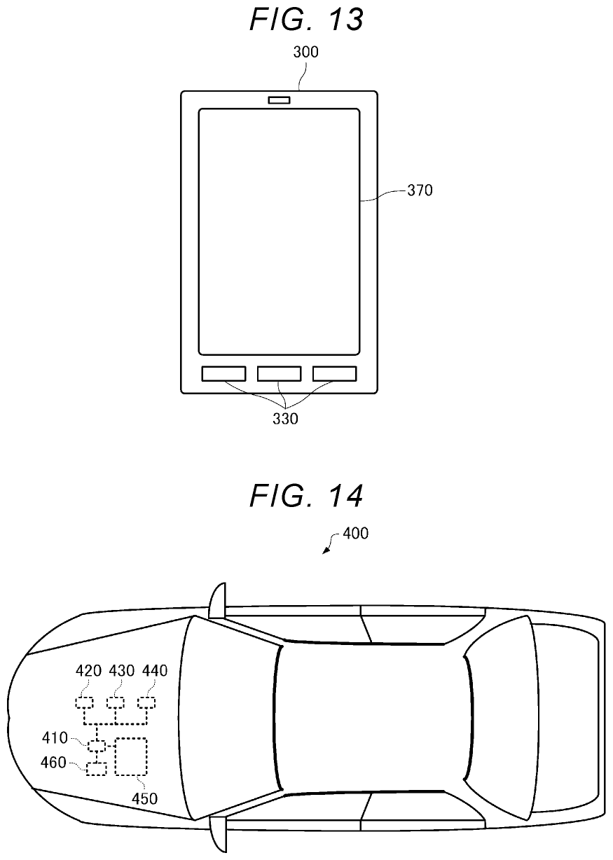

FIG. 13 is a view showing an example of the appearance of a smartphone which is an example of the electronic apparatus 300. The smartphone that is the electronic apparatus 300 includes a button as the operation unit 330 and an LCD as the display unit 370. By applying, for example, the oscillator 1 of each embodiment described above as the oscillator 310, the smartphone that is the electronic apparatus 300 can generate an oscillation signal with higher frequency accuracy as compared with the related art with respect to fluctuations in the outside air temperature, thereby a highly reliable electronic apparatus 300 can be realized.

Further, as another example of the electronic apparatus 300 of the present embodiment, a transmission device functioning as a terminal base station apparatus communicating with, for example, a terminal in a wired or wireless manner, or the like by using the above-described oscillator 310 as a reference signal source is used. By applying, for example, the oscillator 1 of the above-described each embodiment as the oscillator 310, and thus it is also possible to implement the electronic apparatus 300 which is usable in, for example, a communication base station and the like and is desired to have high frequency accuracy, high performance, and high reliability at lower costs than in the related art.

Further, still another example of the electronic apparatus 300 of the present embodiment may be a communication device including a frequency control unit in which the communication unit 360 receives an external clock signal and the processing circuit 320 controls the frequency of the oscillator 310 on the basis of the external clock signal and an output signal of the oscillator 310. The communication device may be a communication apparatus which is used in an apparatus for backbone network such as Stratum 3, or a femtocell.

### 3. Vehicle

FIG. 14 is a view showing an example of a vehicle of the present embodiment. The vehicle 400 shown in FIG. 14 includes an oscillator 410, processing circuits 420, 430, and 440, a battery 450, and a backup battery 460. Note that the vehicle of the present embodiment may be configured such that some of the components shown in FIG. 14 are omitted or changed, or other components are added thereto.

The oscillator 410 includes a circuit device and a resonant element not shown in the drawing, and the circuit device oscillates the resonant element to generate an oscillation signal. The oscillation signal is output to the processing circuits 420, 430, and 440 from an external terminal of the oscillator 410, and is used as, for example, a clock signal.

The processing circuits 420, 430, and 440 operate on the basis of an output signal from the oscillator, and perform various control processing for an engine system, brake system, and a keyless entry system or the like.

The battery 450 supplies power to the oscillator 410 and the processing circuits 420, 430, and 440. The backup battery 460 supplies power to the oscillator 410 and the processing circuits 420, 430, and 440 when an output voltage of the battery 450 falls below a threshold value.

By applying, for example, the oscillator 1 of each embodiment described above as the oscillator 410, it is possible to generate an oscillation signal with higher frequency accuracy as compared with the related art with respect to fluctuations in the outside air temperature, thereby a highly reliable vehicle can be realized.

Various vehicles are conceived as the vehicle 400, and may be, for example, an automobile such as an electric car, an aircraft such as a jet plane or a helicopter, a ship, a rocket, artificial satellite, and the like.

The present disclosure is not limited to the present embodiment, various modifications can be made without departing from the scope of the disclosure.

The above-described embodiments and modification example are just examples, and the disclosure is not limited thereto. For example, each embodiment and the modification example may also be appropriately combined with each other.

The present disclosure includes substantially the same configurations, for example, configurations having the same functions, methods and results, or configurations having the same objects and effects, as the configurations described in the embodiments. In addition, the present disclosure includes a configuration obtained by replacing non-essential portions in the configurations described in the embodiments. Further, the present disclosure includes a configuration that exhibits the same operational effects as those of the configurations described in the embodiments or a configuration capable of achieving the same objects. The present disclosure includes a configuration obtained by adding the configurations described in the embodiments to known techniques.

What is claimed is:

1. An oscillator comprising:
a resonant element;
an oscillation circuit oscillating the resonant element;
a first temperature sensor;
a second temperature sensor that is provided at a location farther fr the resonant element than the first temperature sensor is;
a temperature adjustment element adjusting a temperature of the resonant element; and
a temperature control circuit generating a temperature control signal for controlling the temperature adjustment element on the basis of a temperature set value of the resonant element, a first temperature detection value detected by the first temperature sensor, and a temperature control correction value based on a second temperature detection value detected by the second temperature sensor, wherein
the temperature control correction value approximates a characteristic opposite to a temperature change of the resonant element with respect to an outside air temperature change when the temperature control correction value is zero by a second-order or higher polynomial having the second temperature detection value as a variable.

2. An oscillator comprising:
a resonant element;
an oscillation circuit oscillating the resonant element;
a first temperature sensor;
a second temperature sensor that is provided at a location farther from the resonant element than the first temperature sensor is;
a temperature adjustment element adjusting a temperature of the resonant element; and
a temperature control circuit generating a temperature control signal for controlling the temperature adjustment element on the basis of a temperature set value of the resonant element, a first temperature detection value detected by the first temperature sensor, and a temperature control correction value that is non-linear with respect to a second temperature detection value detected by the second temperature sensor.

3. The oscillator according to claim 1, wherein
the temperature control circuit generates the temperature control signal by comparing a value obtained by adding the temperature set value to the temperature control correction value with the first temperature detection value.

4. The oscillator according to claim 1, wherein
the temperature control circuit generates the temperature control signal by comparing a value obtained by adding the first temperature detection value to the temperature control correction value with the temperature set value.

5. The oscillator according to claim 1, wherein
the temperature control correction value is non-linear with respect to the second temperature detection value in a first range of the second temperature detection value, and
the temperature control correction value is a fixed value regardless of the second temperature detection value in at least one of a lower limit or less of the first range and an upper limit or more of the first range.

6. The oscillator according to claim 1, further comprising:
a temperature compensation circuit that compensates a frequency of the oscillation circuit on the basis of the second temperature detection value.

7. The oscillator according to claim 1, further comprising:
a first circuit device and a second circuit device, wherein
the oscillation circuit and the temperature control circuit are provided in the first circuit device, and
the first temperature sensor and the temperature adjustment element are provided in the second circuit device.

8. The oscillator according to claim 7, wherein
the resonant element is bonded to the second circuit device.

9. The oscillator according to claim 7, further comprising:
a container accommodating the resonant element, the first circuit device, and the second circuit device, wherein
1the second temperature sensor is provided in the first circuit device.

10. The oscillator according to claim 7, further comprising:
a container accommodating the resonant element, the first circuit device, and the second circuit device, wherein
the second temperature sensor is provided outside the container.

11. An electronic apparatus comprising:
the oscillator according to claim 1; and
a processing circuit operating on the basis of an output signal from the oscillator.

12. A vehicle comprising:
the oscillator according to claim 1; and
a processing circuit operating on the basis of an output signal from the oscillator.
